(19) United States
(12) Patent Application Publication
(10) Pub. No.: US 2025/0382519 A1
(43) Pub. Date: Dec. 18, 2025

(54) P-TYPE DOPING METHOD OF LEAD-FREE PEROVSKITES AND LEAD-FREE PEROVSKITE THIN FILM TRANSISTOR DEVICE USING THE SAME

(71) Applicant: GWANGJU INSTITUTE OF SCIENCE AND TECHNOLOGY, Gwangju (KR)

(72) Inventors: Kwang Hee LEE, Gwangju (KR); Ju Hyeon KIM, Gwangju (KR)

(21) Appl. No.: 18/991,306

(22) Filed: Dec. 20, 2024

(30) Foreign Application Priority Data
Jun. 13, 2024 (KR) 10-2024-0076919

(51) Int. Cl. C09K 11/02; C09K 11/06; H10K 10/46

(52) U.S. Cl. CPC C09K 11/02; C09K 11/06; H10K 10/484; C09K 2211/1483; C09K 2211/188

(57) ABSTRACT

The present inventive concept relates to a p-type doping method of lead-free perovskites and lead-free perovskite-based thin film transistor devices using the same. When lead-free perovskites are surface-treated with polymer materials including thiophene functional groups, p-type doping is induced through the interaction. Thus, it is possible to improve the electrical and optical properties of the lead-free perovskites.

### CLAIM FOR PRIORITY

This application claims priority to Korean Patent Application No. 10-2024-0076919 filed on June 13, 2024 in the Korean Intellectual Property Office (KIPO), the entire contents of which are hereby incorporated by reference.

### BACKGROUND

### 1. Technical Field

Example embodiments of the present inventive concept relate, in general, to a p-type doping method for lead-free perovskites and to lead-free perovskite thin-film transistor devices using the method. More specifically, the inventive concept concerns a method of inducing p-type doping by surface-treating lead-free perovskites with polymer materials containing thiophene functional groups. This treatment improves the electrical properties of the lead-free perovskites and enhances the performance and stability of lead-free perovskite thin film transistors.

### 2. Related Art

As semiconductor performance becomes increasingly due to technological advancements and the development of computers and communication devices, perovskites are gaining attention as semiconductor materials. A perovskite (ABX₃) is an octahedral-structured material, where A is an organic cation, B is a transition metal, and X is a halide anion. Perovskites can be used in both dry and wet processes, allow for low-temperature processing, and exhibit higher charge carrier mobility compared to conventional materials.

Conventional perovskites usually contain lead or tin ions, but lead ions contribute to environmental pollution. Consequently, research into lead-free perovskites is underway. However, lead-free perovskites tend to have low crystallinity and numerous defect sites, which reduces the material's electrical properties and leads to low-charge carrier mobility in semiconductor devices.

Therefore, there is a need to develop a doping method that can manufacture lead-free perovskites with high charge carrier mobility and stability, similar to those of silicon-based semiconductors.

### SUMMARY

Accordingly, example embodiments of the present inventive concept are provided to substantially obviate one or more problems due to the limitations and disadvantages of the related art.

Example embodiments of the present inventive concept provide a p-type doping method of lead-free perovskites.

Example embodiments of the present inventive concept also provide lead-free perovskite-based thin film transistor devices including lead-free perovskites manufactured through the above-described method.

In some example embodiments, a p-type doping method for lead-free perovskites is provided. In this method, p-type doping of lead-free perovskites is induced by coating the top surface of the lead-free perovskite with a solution including several kinds of polymer materials with thiophene functional groups. The polymer materials are represented by the following Chemical Formula 1 or Chemical Formula 2,

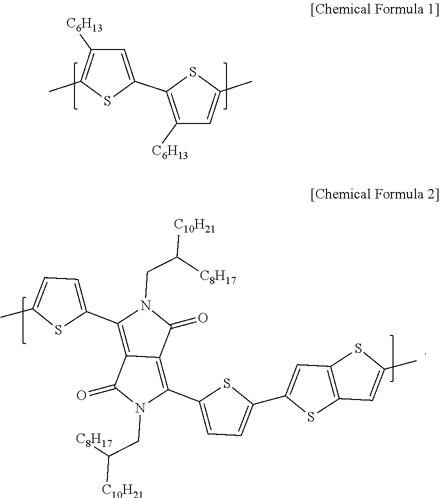

In other example embodiments, lead-free perovskite-based thin film transistor devices are provided, which includes a p-type doped lead-free perovskite manufactured through the above-described method. The lead-free perovskite-based thin film transistor devices may have a structure in which a gate electrode, a gate dielectric layer, a channel layer composed of lead-free perovskites, and a doping induction layer including a polymer material with thiophene functional groups are sequentially stacked. Additionally, a source electrode and a drain electrode may be formed on both ends of the doping induction layer. The polymer materials are represented by the following Chemical Formula 3 or Chemical Formula 4,

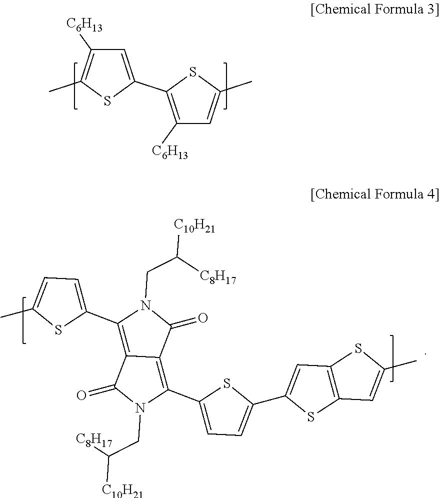

### BRIEF DESCRIPTION OF DRAWINGS

Example embodiments of the present inventive concept will become more apparent by describing in detail example embodiments of the present inventive concept with reference to the accompanying drawings, in which:

FIG. 1 is a schematic diagram of lead-free perovskite-based thin film transistor devices according to a preferred embodiment of the present inventive concept;

FIG. 2 is a schematic diagram illustrating the interaction between lead-free perovskites and polymer materials according to a preferred embodiment of the present inventive concept;

FIG. 3 shows time-resolved fluorescence mapping images according to a preferred embodiment of the present inventive concept;

FIG. 4 shows graphs measuring photoluminescence characteristics according to a preferred embodiment of the present inventive concept;

FIG. 5 shows X-ray photoelectron spectroscopy data according to a preferred embodiment of the present inventive concept;

FIG. 6 shows Fourier-transform infrared spectroscopy spectra according to a preferred embodiment of the present inventive concept;

FIG. 7 shows energy band structure and Hall effect measurement graphs according to a preferred embodiment of the present inventive concept;

FIG. 8 shows transistor performance evaluation graphs according to the concentration of a preferred embodiment of the present inventive concept;

FIG. 9 shows transistor performance evaluation graphs according to a preferred embodiment of the present inventive concept;

FIG. 10 shows charge carrier mobility graphs according to a preferred embodiment of the present inventive concept;

FIG. 11 shows graphs evaluating operational and voltage stress stability according to a preferred embodiment of the present inventive concept; and

FIG. 12 shows a contact resistance test graph according to a preferred embodiment of the present inventive concept.

### DESCRIPTION OF EXAMPLE EMBODIMENTS

Since the present inventive concept is susceptible to various modifications and alternative forms, specific embodiments are shown by way of examples in the drawings and described in detail herein. However, it should be understood that there is no intent to limit the present inventive concept to the particular forms disclosed. On the contrary, the present inventive concept is to cover all modifications, equivalents, and alternatives falling within the spirit and scope of the inventive concept.

Unless otherwise defined, all terms (including technical and scientific terms) used herein have the same meaning as commonly understood by those of ordinary skill in the art to which this inventive concept belongs. Furthermore, Terms defined in commonly used dictionaries should be interpreted as having meanings consistent with use in the relevant art, and not in an idealized or overly formal sense unless expressly defined herein.

In this specification, when a part such as a layer, film, or plate is described as being “on” or “above” another part, it includes not only the case where it is directly on the other part but also where there is another part in between.

Hereinafter, various example embodiments of the present inventive concept will be described in detail with reference to the attached drawings.

### EXAMPLE

The present inventive concept provides a p-type doping method of lead-free perovskites. For the lead-free perovskite, p-type doping is induced through a first step (S10) of preparing lead-free perovskites; and a second step (S20) of coating the surface of the lead-free perovskites prepared in the first step (S10) with a solution including polymer materials with thiophene functional groups.

The first step (S10) involves preparing lead-free perovskites, which may be preliminary quasi-two-dimensional perovskite materials. Quasi-two-dimensional perovskites are formed by arranging large two-dimensional organic cations on three-dimensional octahedral inorganic layers. This arrangement disrupts the three-dimensional structure, dividing it into multiple layers along a specific axis. The large two-dimensional organic cations exhibit insulating properties, forming large energy barriers on both sides of the octahedral structure. Thus, depending on the extent to which exciton formation is physically restricted along the thickness direction, stable excitons with high formation energy may be present. Furthermore, the band gap and optical/electrical properties can be easily adjusted based on the number of layers. However, when quasi-two-dimensional perovskites are used alone, issues such as low crystallinity and numerous defects. Nevertheless, when they interact with polymer materials including thiophene functional groups through the present inventive concept, p-type doping may be induced, addressing these problems.

The second step (S20) is for coating the surface of the lead-free perovskite prepared in the first step (S10) with a solution including polymer materials with thiophene functional groups to form a doping induction layer on the surface of the lead-free perovskites.

When a polymer material with thiophene functional groups is applied on the surface of the lead-free perovskites, p-type doping of the lead-free perovskites may be induced through a molecular-level interaction between tin ions of the lead-free perovskites and sulfur atoms of the polymer materials. When tin ions of the lead-free perovskites are oxidized due to the interaction between tin and sulfur, hole sources are generated, enabling p-doping mediated by surface electronic impurities.

The polymer materials with thiophene functional groups may be conductive polymer materials that have electrical properties due to pi-conjugation at the center based on the thiophene functional groups.

It is preferable that the polymer material is poly(3-hexylthiophene) (P3HT) represented by the following Chemical Formula 1 or poly[2,5-(octyldodecyl)-3,6-diketopyrrolopyrrole-alt-5,5-(2,5-di(thien-2-yl)thieno[3,2-b]thiophene)] (TT) represented by the following Chemical Formula 2.

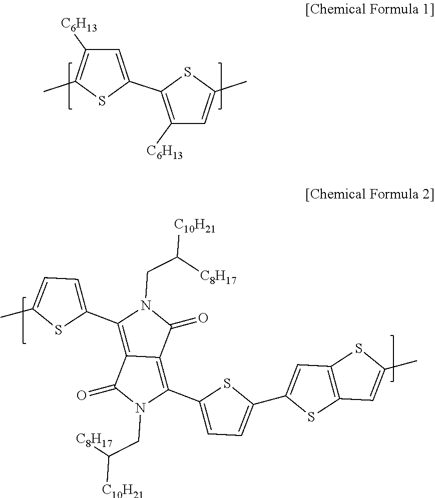

The polymer materials are preferably added at a concentration of 0.5 mg/mL to 4.0 mg/mL in the solution, more preferably 0.5 mg/mL to 2.0 mg/mL, and even more preferably 0.7 mg/mL to 1.5 mg/mL. When the concentration of the polymer materials is less than 0.5 mg/mL, it may be insufficient to interact with tin atoms of the lead-free perovskites, and thus p-type doping may not be induced. On the other hand, when the concentration of the polymer materials is greater than 4.0 mg/mL, the polymer materials may become the main semiconductor channel. In this case, since the charge moves along the polymer materials, the performance of the transistor may vary depending on the physical properties of the polymer materials.

The present inventive concept provides lead-free perovskite-based thin film transistor devices in which polymer materials with thiophene functional groups form a doping induction layer on the surface of the lead-free perovskites.

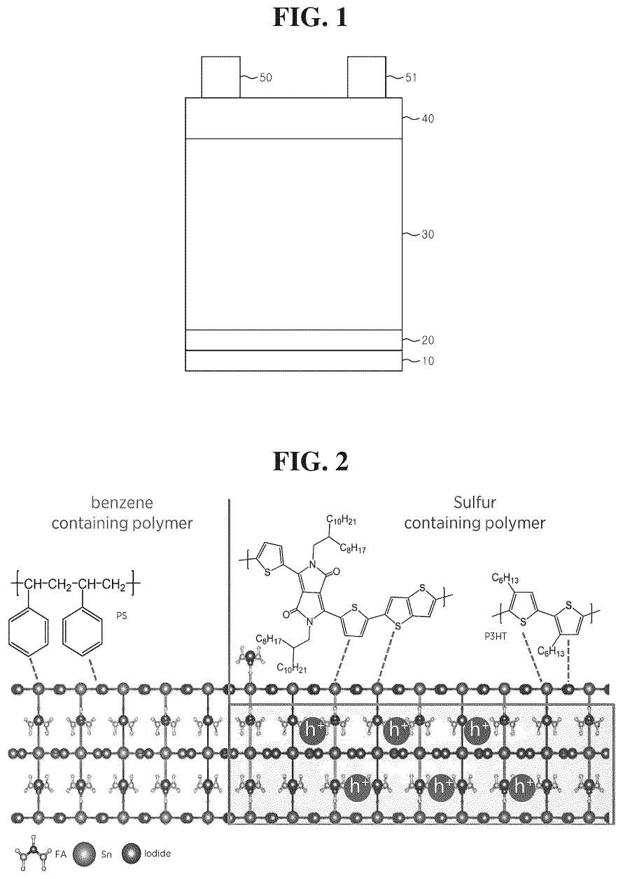

FIG. 1 is a schematic diagram of lead-free perovskite-based thin film transistor devices according to an embodiment of the present inventive concept.

Referring to FIG. 1, the lead-free perovskite-based thin film transistor devices are composed of a gate electrode 10, a gate dielectric layer 20 formed on the gate electrode 10, a channel layer 30 of lead-free perovskites formed on the gate dielectric layer 20, a doping induction layer 40 formed on the channel layer 30 and including polymer materials with thiophene functional groups, and a source electrode 50 and a drain electrode 51, which are formed on the doping induction layer 40. However, the lead-free perovskite-based thin film transistor devices are not limited to the above-described configuration, and one or more components may be added in each layer.

The channel layer 30 may be composed of a preliminary quasi-two-dimensional perovskite material. Quasi-two-dimensional perovskites are formed by arranging large two-dimensional organic cations on three-dimensional octahedral inorganic layers, which prevents the perovskite from maintaining a three-dimensional structure and divides a single three-dimensional structure into multiple layers along a specific axis. The large two-dimensional organic cations have insulating properties, forming large energy barriers on both sides of the octahedral structure. Thus, depending on the extent to which the physical formation of excitons is limited in the thickness direction, stable excitons with high formation energy may be present, and it is easy to adjust the band gap and optical/electrical properties depending on the number of layers. However, when quasi-two-dimensional perovskite is used alone, there are problems with low crystallinity and numerous defects. Nevertheless, when it interacts with polymer materials including thiophene functional groups through the present inventive concept, p-type doping may be induced in the perovskite to solve these problems.

The doping induction layer 40 is formed by applying the polymer materials with thiophene functional groups on the surface of the channel layer 30 of the lead-free perovskites. The doping induction layer 40 may induce p-type doping in the lead-free perovskites through a molecular-level interaction between tin ions of the lead-free perovskites and sulfur atoms of the polymer materials. When tin ions of the lead-free perovskites are oxidized due to the interaction between tin and sulfur, hole sources are generated, enabling p-doping mediated by surface electronic impurities.

The polymer materials with thiophene functional groups in the doping induction layer 40 may be conductive polymer materials that have electrical properties due to pi-conjugation at the center based on the thiophene functional groups.

It is preferable that the polymer materials are poly(3-hexylthiophene) (P3HT) represented by the following Chemical Formula 3 or poly[2,5-(octyldodecyl)-3,6-diketopyrrolopyrrole-alt-5,5-(2,5-di(thien-2-yl)thieno[3,2-b]thiophene)] (TT) represented by the following Chemical Formula 4.

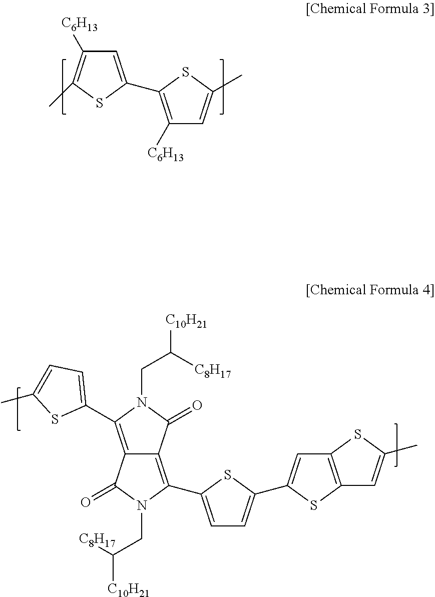

The polymer materials are preferably added at a concentration of 0.5 mg/mL to 4.0 mg/mL in the solution, more preferably 0.5 mg/mL to 2.0 mg/mL, and even more preferably 0.7 mg/mL to 1.5 mg/mL. When the concentration of the polymer materials is less than 0.5 mg/mL, it may be insufficient to interact with tin ions of the lead-free perovskites, and thus p-type doping may not be induced. On the other hand, when the concentration of the polymer materials is greater than 4.0 mg/mL, the polymer materials may become the main semiconductor material channel. Accordingly, since the charge moves along the polymer materials, the performance of the transistor may vary depending on the physical properties of the polymer materials.

FIG. 2 is a schematic diagram illustrating the interaction between lead-free perovskites and polymer materials according to a preferred embodiment of the present inventive concept.

Referring to FIG. 2, it can be seen that compared to polystyrene (PS) on the left, which is a non-conjugated polymer without thiophene functional groups, P3HT and TT on the right, which are conjugated polymers including thiophene functional groups, improve the density and mobility of carriers through the interaction between sulfur and tin.

### Preparation Example 1-1: Manufacture of Lead-Free Perovskite Thin Film Including P3HT at Concentration of 1.0 mg/ml

A silicon substrate was used as a gate electrode, and silicon oxide (SiO₂) was vacuum deposited to a thickness of 150 nm on the gate electrode to form a gate dielectric layer. To form a lead-free perovskite channel layer on the gate dielectric layer, 0.057 mM of phenylethylamine hydroiodide (PEAI, 14.23 mg), 0.17 mM of formamidinium iodide (FAI, 29.48 mg), 0.2 mM of SnI₂ (437.96 mg), and 0.02 mM of SnF (3.13 mg) as solutes were dissolved in a solvent of 800 μL of dimethylformamide (DMF) and 200 μL of dimethyl sulfoxide (DMSO) to prepare a lead-free perovskite precursor solution. After applying the lead-free perovskite precursor solution on the upper surface of the gate dielectric layer, spin coating was performed at 5,000 rpm for 60 seconds to form a lead-free perovskite thin film. At this time, to form crystals of the lead-free perovskite thin film, while the lead-free perovskite precursor solution was spin-coated, chlorobenzene (CB) solution was sprayed 15 seconds after starting the spin coating. After completing the spin coating, the substrate on which the lead-free perovskite thin film was formed was heat treated on a hot plate maintained at 100° C. for 7 minutes to manufacture a (PEA)₂(FA)₆Sn₇I₂₂ lead-free perovskite channel layer in the form of a film.

To form a doping induction layer on the lead-free perovskite channel layer, a diluted solution was prepared by diluting the P3HT compound to 1.0 mg/mL in CB. The diluted solution was spin-coated on the lead-free perovskite channel layer at 5,000 rpm for 30 seconds to manufacture a lead-free perovskite thin film including P3HT.

### Preparation Example 1-2: Manufacture of Lead-Free Perovskite Thin Film Including P3HT at Concentration of 0.5 mg/mL

A thin film was manufactured under the same conditions as in Preparation Example 1-1, except that the concentration of P3HT was 0.5 mg/mL.

### Preparation Example 1-3: Manufacture of Lead-Free Perovskite Thin Film Including P3HT at Concentration of 2.0 mg/mL

A thin film was manufactured under the same conditions as in Preparation Example 1-1, except that the concentration of P3HT was 2.0 mg/mL.

### Preparation Example 2-1: Manufacture of Lead-Free Perovskite Thin Film Including TT at Concentration of 1.0 mg/mL

A thin film was manufactured under the same conditions as in Preparation Example 1-1, except that the TT compound was added instead of the P3HT compound.

### Preparation Example 2-2: Manufacture of Lead-Free Perovskite Thin Film Including TT at Concentration of 0.5 mg/ml

A thin film was manufactured under the same conditions as in Preparation Example 2-1, except that the concentration of TT was 0.5 mg/mL.

### Preparation Example 2-3: Manufacture of Lead-Free Perovskite Thin Film Including TT at Concentration of 2.0 mg/ml

A thin film was manufactured under the same conditions as in Preparation Example 2-1, except that the concentration of TT was 2.0 mg/mL.

### Preparation Example 2-4: Manufacture of Lead-Free Perovskite Thin Film Including TT at Concentration of 4.0 mg/ml

A thin film was manufactured under the same conditions as in Preparation Example 2-1, except that the concentration of TT was 4.0 mg/mL.

### Comparative Example 1: Manufacture of Lead-Free Perovskite Thin Film without Doping Induction Layer

A silicon substrate was used as a gate electrode, and silicon oxide (SiO₂) was vacuum deposited to a thickness of 150 nm on the gate electrode to form a gate dielectric layer. To form a lead-free perovskite channel layer on the gate dielectric layer, 0.057 mM of PEAI (14.23 mg), 0.17 mM of FAI (29.48 mg), 0.2 mM of SnI₂ (437.96 mg), and 0.02 mM of SnF (3.13 mg) as solutes were dissolved in a solvent of 800 μL of DMF and 200 μL of DMSO to prepare a lead-free perovskite precursor solution. After applying the lead-free perovskite precursor solution on the upper surface of the gate dielectric layer formed on the gate electrode, the spin coating was performed at 5,000 rpm for 60 seconds to form a lead-free perovskite thin film. At this time, to form crystals of the lead-free perovskite thin film, while the lead-free perovskite precursor solution was spin-coated, a CB solution was sprayed 15 seconds after starting the spin coating. After completing the spin coating, the substrate on which the lead-free perovskite thin film was formed was heat treated on a hot plate maintained at 100° C. for 7 minutes to manufacture a (PEA)₂(FA)₆Sn₇I₂₂ lead-free perovskite channel layer in the form of a film, a lead-free perovskite thin film without a doping induction layer.

### Comparative Example 2-1: Manufacture of Lead-Free Perovskite Thin Film Including PS at Concentration of 1.0 mg/mL

To form a doping induction layer on the lead-free perovskite channel layer under the conditions of Comparative Example 1, a diluted solution was prepared by diluting the PS compound to 1.0 mg/mL in CB. The diluted solution was spin-coated on the lead-free perovskite channel layer at 5,000 rpm for 30 seconds to manufacture a lead-free perovskite thin film including PS.

### Comparative Example 2-2: Manufacture of Lead-Free Perovskite Thin Film Including PS at Concentration of 0.5 mg/mL

A thin film was manufactured under the same conditions as in Comparative Example 2-1, except that the concentration of PS was 0.5 mg/mL.

### Comparative Example 2-3: Manufacture of Lead-Free Perovskite Thin Film Including PS at Concentration of 2.0 mg/ml

A thin film was manufactured under the same conditions as in Comparative Example 2-1, except that the concentration of PS was 2.0 mg/mL.

### Comparative Example 2-4: Manufacture of Lead-Free Perovskite Thin Film Including PS at Concentration of 4.0 mg/mL

A thin film was manufactured under the same conditions as in Comparative Example 2-1, except that the concentration of PS was 4.0 mg/mL.

### Measurement Example 1

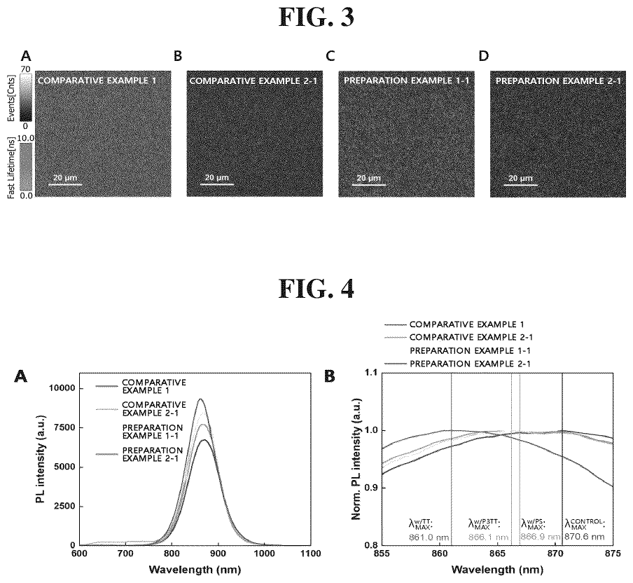

FIG. 3 shows time-resolved fluorescence mapping images of Comparative Example 1, Comparative Example 2-1, Preparation Example 1-1, and Preparation Example 2-1, and FIG. 4 shows graphs measuring the photoluminescence characteristics of Comparative Example 1, Comparative Example 2-1, Preparation Example 1-1, and Preparation Example 2-1.

Referring to FIG. 3, Comparative Example 1 appeared mainly green, indicating low charge transfer or low charge carrier mobility. Comparative Example 2-1 showed a slightly reddish color compared to Comparative Example 1, but the degree of redness was lower than that observed in Preparation Examples 1-1 and 2-1. Preparation Examples 1-1 and 2-1 showed a higher proportion of red color, indicating that excellent charge transfer and charge carrier mobility are possible through the passivation of defects present on the surface of the lead-free perovskite thin film and p-type doping. Therefore, it can be seen that compared to Comparative Examples 1 and 2-1, Preparation Examples 1-1 and 2-1 are capable of excellent charge transfer and charge carrier mobility, and Preparation Example 2-1 exhibits the best performance.

Referring to FIG. 4, FIG. 4A and FIG. 4B are photoluminescence spectra. As shown in FIG. 4A, it was observed that the height of the peak increased and the width widened in the order of Comparative Example 1, Comparative Example 2-1, Preparation Example 1-1, and Preparation Example 2-1. Therefore, it can be seen that the lead-free perovskite doped with polymer materials has excellent luminescence intensity and crystal structure compared to the lead-free perovskite without a doping induction layer, and Preparation Examples 1-1 and 2-1 in which the doping induction layer was formed with polymer materials including thiophene functional groups exhibit much better performance. In addition, when comparing Comparative Examples and Preparation Examples in FIG. 4B, a blue shift of the peak was observed, suggesting the luminescence efficiency was improved and p-type doping was achieved.

Therefore, through FIG. 3 and FIG. 4, it can be seen that the charge carrier mobility of the lead-free perovskites of Preparation Examples 1-1 and 2-1 is increased through p-type induction doping, enabling smooth charge transport, and thus the optical properties are increased.

### Measurement Example 2

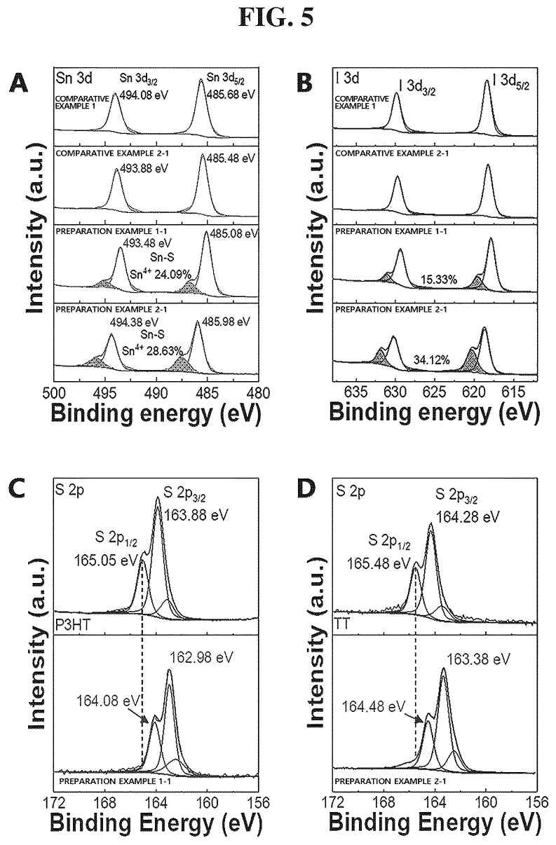

FIG. 5 shows graphs of X-ray photoelectron spectroscopy data of Comparative Example 1, Comparative Example 2-1, Preparation Example 1-1, and Preparation Example 2-1.

Referring to FIG. 5, in addition to the two peaks observed in Comparative Examples 1 and 2-1 in FIG. 5A, new peaks were observed in Preparation Examples 1-1 and 2-1, and on the graphs for the sulfur element in FIG. 5C and FIG. 5D, when comparing the polymer material and Preparation Examples 1-1 and 2-1, there was a difference in peaks, which indicates that sulfur and tin interact on the surface of the lead-free perovskites. Likewise, in FIG. 5B, it can be seen that a new peak that was not observed in Comparative Examples 1 and 2-1 appeared in Preparation Examples 1-1 and 2-1.

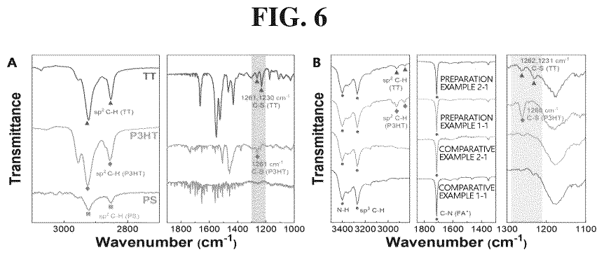

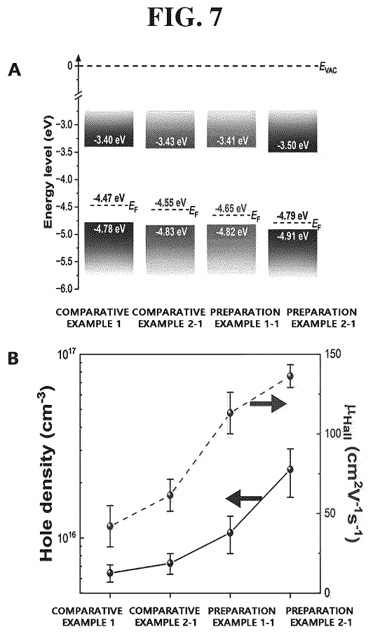

FIG. 6 shows Fourier-transform infrared spectroscopy analysis graphs. FIG. 6A relates to TT, P3HT, and PS, which are polymer materials treated on the surface of perovskite, and FIG. 6B relates to Comparative Example 1, Comparative Example 2-1, Preparation Example 1-1, and Preparation Example 2-1.

Referring to FIG. 6, in FIG. 6A, C—S bond peaks that did not appear in PS were observed in TT and P3HT at about 1261 cm⁻¹. In FIG. 6B, C—S bond peaks were also observed in Preparation Examples 1-1 and 2-1, but compared to FIG. 6A, the strength of the C—S bond decreased. This was because sulfur in the C—S bond of the thiophene functional groups of the polymers of Preparation Examples 1-1 and 2-1 interacted with tin ions on the surface of the lead-free perovskites.

Therefore, through FIG. 5 and FIG. 6, it can be seen that molecular level interactions occur on the surface of lead-free perovskites in Preparation Examples 1-1 and 2-1.

### Measurement Example 3

FIG. 7 shows the energy band structure and Hall effect measurement graphs of Comparative Example 1, Comparative Example 2-1, Preparation Example 1-1, and Preparation Example 2-1. For the measurement, transistor devices including Comparative Examples and Preparation Examples were manufactured and referred to as Comparative Example 1, Comparative Example 2-1, Preparation Example 1-1, and Preparation Example 2-1.

The transistor devices used for the measurement were manufactured by vacuum depositing Au to a thickness of 70 nm on the surfaces of Comparative Examples 1 and 2-1 and Preparation Examples 1-1 and 2-1, respectively, to form source and drain electrodes.

Referring to FIG. 7, in FIG. 7A, the Fermi energy level decreased in the order of Comparative Example 1 to Preparation Example 2-1, and in FIG. 7B, Preparation Examples had excellent hole density and charge carrier mobility compared to Comparative Examples.

Therefore, it can be seen that Preparation Examples 1-1 and 2-1 induce p-type doping through polymer materials including thiophene functional groups on the surface of the lead-free perovskites, and thus the perovskites exhibit excellent performance.

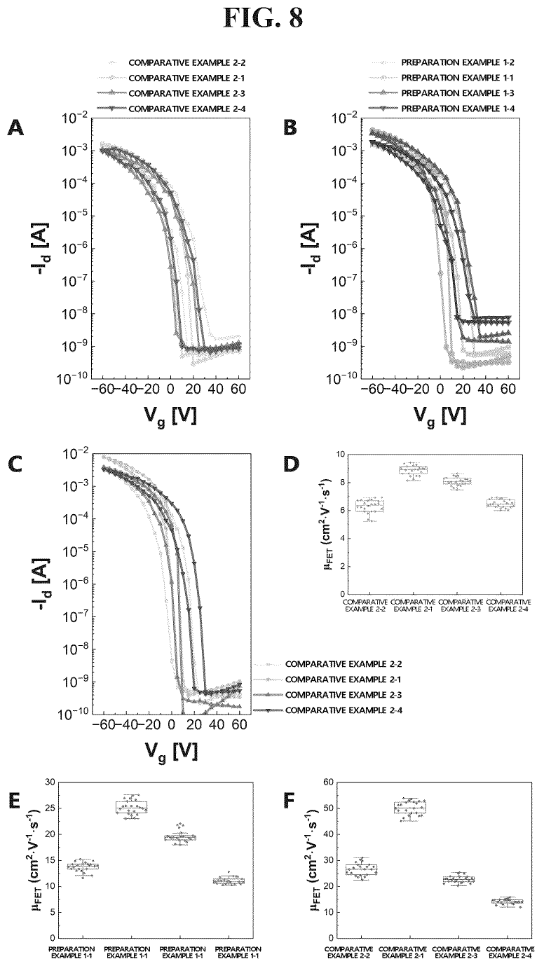

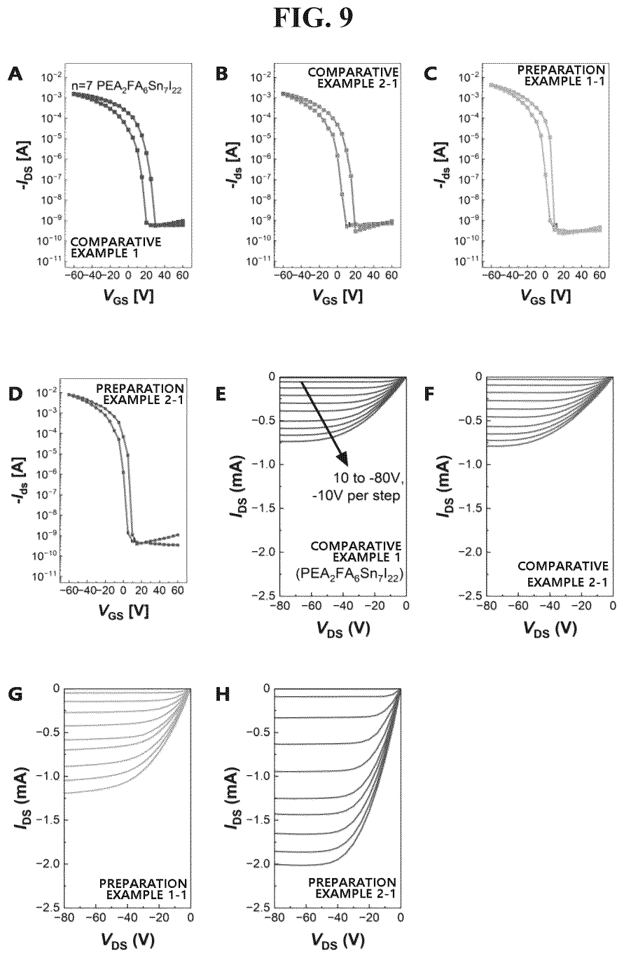

FIG. 8 shows graphs comparing the performance of transistor devices according to the concentration of Comparative Examples and Preparation Examples with polymer materials applied on the surface of lead-free perovskites, and FIG. 9 shows graphs comparing the performance of transistor devices of Comparative Example 1, which is a lead-free perovskite without surface coating, and Comparative Example 2-1 and Preparation Examples 1-1 and 2-1, which are surfaced coated.

Referring to FIG. 8, compared to FIG. 8A using a non-conjugated polymer, PS, FIG. 8B and FIG. 8C using conjugated polymers, P3HT and TT, showed excellent performance. When comparing FIG. 8D to FIG. 8F, higher charge carrier mobility was measured. In addition, the charge carrier mobility of Preparation Examples was different depending on the concentration, but Preparation Examples exhibited excellent performance compared to Comparative Example 2-1, which had the best performance among Comparative Examples. Therefore, it can be seen that the concentration of the polymer material of the doping induction layer formed on the surface of the lead-free perovskites is preferably 0.5 mg/mL to 4.0 mg/mL.

Referring to FIG. 9, when comparing Comparative Example 1 and Comparative Example 2-1, which exhibited the best performance in FIG. 8, with Preparation Examples 1-1 and 2-1, it can be seen that Preparation Examples 1-1 and 2-1 exhibited excellent transistor performance compared to Comparative Examples 1 and 2-1.

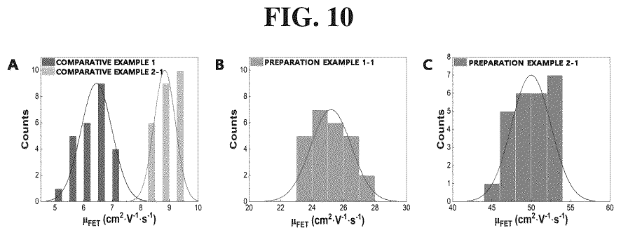

FIG. 10 shows graphs of charge carrier mobility calculated from the values measured in FIG. 9.

Referring to FIG. 10, Comparative Example 2-1 showed a slight increase in charge carrier mobility compared to Comparative Example 1. On the other hand, Preparation Example 1-1 and Preparation Example 2-1 showed a significant increase in charge carrier mobility, approximately 4 times and 8 times higher, respectively, compared to Comparative Example 1.

Therefore, compared to conventional transistor devices, the use of P3HT as a p-type doping induction layer results in excellent transistor performance, while the use of TT may result in much better transistor performance.

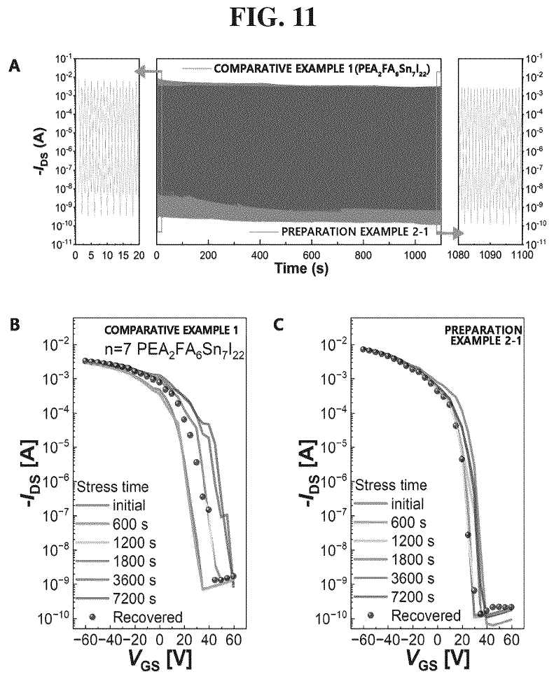

FIG. 11 are graphs measuring the operational and voltage stress stability of Comparative Example 1 and Preparation Example 2-1.

Referring to FIG. 11, FIG. 11A shows the results of about 1,100 on/off switching tests. While Preparation Example 2-1 maintained a constant value, Comparative Example 1 had changes compared to its initial performance after testing it about 200 times.

In addition, when comparing FIG. 11B and FIG. 11C, Preparation Example 2-1 had values similar to its initial state even with changes in stress time, unlike Comparative Example 1. Therefore, it can be seen that Preparation Example 2-1 has excellent stability.

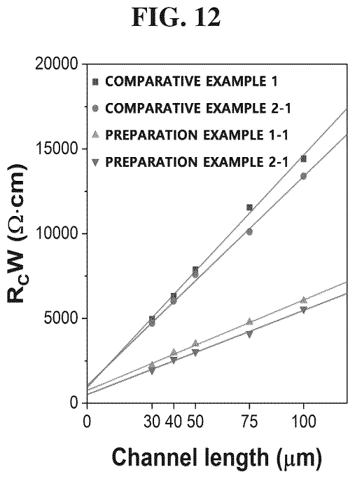

FIG. 12 shows graphs of contact resistance measurement results for Comparative Example 1, Comparative Example 2-1, Preparation Example 1-1, and Preparation Example 2-1.

Referring to FIG. 12, the experimental results show that Comparative Examples 1 and 2-1 had a contact resistance of 1,000 £Ωcm, Preparation Example 1-1 had a contact resistance of 750 Ωcm, and Preparation Example 2-1 had a contact resistance of 500 Ωcm. Therefore, the lead-free perovskite-based thin film transistor devices using P3HT or TT of the present inventive concept have lower resistance values compared to conventional devices, with the best performance achieved when using TT as the doping induction layer.

According to the present inventive concept described above, p-type doping of lead-free perovskites can be induced by applying a polymer material including a functional group of thiophene on the surface of the lead-free perovskites. As p-type doping is induced through the molecular level interaction between the lead-free perovskites and the polymer materials, the electrical properties of the lead-free perovskite are improved, thereby enabling smooth charge transport. Thus, when manufacturing transistor devices including lead-free perovskites, the charge carrier mobility and operational stability of the devices can be improved. In addition, it is possible to improve the performance of lead-free perovskites using a relatively simple method such as low-temperature solution processing, making the process easier.

In addition to transistor devices, it can be applied in fields such as neuromorphic devices, which are optical semiconductor devices using perovskites, optical sensors, semiconductor devices for quantum computing, light-emitting diodes, and photoelectrochemical cells.

While the example embodiments of the present inventive concept and their advantages have been described in detail, it should be understood that various changes, substitutions and alterations may be made herein without departing from the scope of the inventive concept.

### LIST OF REFERENCE NUMERALS

10: Gate electrode
20: Gate dielectric layer
30: Lead-free perovskite
40: Doping induction layer
50: Source electrode
51: Drain electrode

What is claimed is:

1. A p-type doping method of lead-free perovskites comprising:
Preparing lead-free perovskites; and
coating the surface of the lead-free perovskites with a solution including polymer materials with thiophene functional groups.

2. The method of claim 1, wherein the polymer material is poly(3-hexylthiophene) (P3HT) represented by the following Chemical Formula 1,

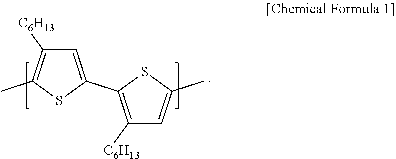

3. The method of claim 1, wherein the polymer material is poly[2,5-(octyldodecyl)-3,6-diketopyrrolopyrrole-alt-5,5-(2,5-di(thien-2-yl)thieno[3,2-b]thiophene)] (TT) represented by the following Chemical Formula 2,

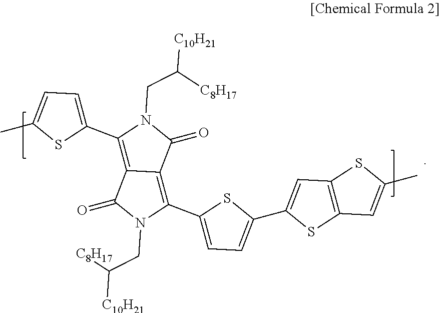

4. The method of claim 1, wherein the polymer material has a concentration of 0.5 mg/mL to 4.0 mg/mL in the solution.

5. The method of claim 1, wherein the lead-free perovskites are quasi-two-dimensional perovskites.

6. The method of claim 1, wherein p-type doping in the lead-free perovskites is induced through a molecular-level interaction between tin ions of the lead-free perovskites and sulfur atoms of the polymer materials.

7. A perovskite thin film transistor device comprising:
a gate electrode;
a gate dielectric layer formed on the gate electrode;
a channel layer of lead-free two-dimensional perovskites formed on the gate dielectric layer;
a doping induction layer formed on the channel layer and including polymer materials with thiophene functional groups; and
a source electrode and a drain electrode, which are formed on both side ends of the doping induction layer.

8. The device of claim 7, wherein the doping induction layer includes polymer materials represented by the following Chemical Formula 3,
[Chemical Formula 3]

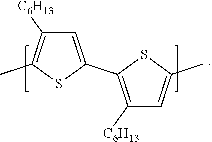

9. The device of claim 7, wherein the doping induction layer includes a polymer material represented by the following Chemical Formula 4,

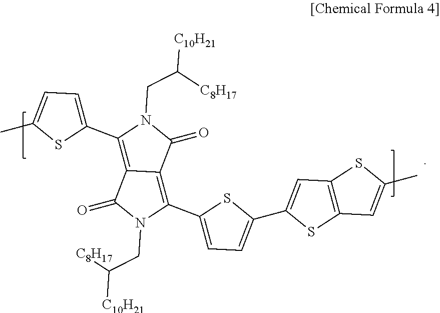

10. The device of claim 7, wherein p-type doping is induced in the channel layer through the reaction of sulfur in the doping induction layer with tin in the channel layer.
